(19) United States
(12) Patent Application Publication
(10) Pub. No.: US 2026/0221092 A1
(43) Pub. Date: Jul. 30, 2026

(54) DISPLAY DEVICE, CONTROL METHOD FOR DISPLAY PANEL, AND ELECTRONIC DEVICE

(71) Applicant: SONY SEMICONDUCTOR SOLUTIONS CORPORATION, KANAGAWA (JP)

(72) Inventor: IKUHIRO YAMAMURA, KANAGAWA (JP)

(21) Appl. No.: 19/143,541

(22) PCT Filed: Dec. 6, 2023
(86) PCT No.: PCT/JP2023/043577

§ 371 Date: Jun. 26, 2025

(30) Foreign Application Priority Data
Jan. 4, 2023 (JP) 2023-000303

(51) Int. Cl. G09G 3/3233

(52) U.S. Cl. CPC G09G 3/3233; G09G 2300/0819; G09G 2310/0245; G09G 2310/0294; G09G 2330/021; G09G 2330/045

(57) ABSTRACT

A display device includes: a display panel including a plurality of pixels; and a control unit that controls the display panel, in which the display panel includes a plurality of pixel blocks each including one or more pixels, the plurality of pixel blocks includes a first pixel block and a second pixel block, and the control unit controls the display panel such that a refresh rate of a pixel in the second pixel block is lower than a refresh rate of a pixel in the first pixel block.

### FIELD

The present disclosure relates to a display device, a control method for a display panel, and an electronic device.

### BACKGROUND

Various types of technology have been proposed for a display device including a display panel using an organic light emitting diode (OLED) or the like (see, for example, Patent Literature 1).

### CITATION LIST

### Patent Literature

Patent Literature 1: JP 2010-97097 A
Patent Literature 2: WO 2014/103500 A

### SUMMARY

### Technical Problem

With an increase in the number of pixels and an increase in the frame rate of display devices, there are emerging issues of an increase in the power consumption and heat generation.

An aspect of the present disclosure suppresses power consumption and heat generation.

### Solution to Problem

A display device according to one aspect of the present disclosure includes: a display panel including a plurality of pixels; and a control unit that controls the display panel, wherein the display panel includes a plurality of pixel blocks each including one or more of the pixels, the plurality of pixel blocks includes a first pixel block and a second pixel block, and the control unit controls the display panel such that a refresh rate of a pixel in the second pixel block is lower than a refresh rate of a pixel in the first pixel block.

A control method according to one aspect of the present disclosure includes a display panel including a plurality of pixels, wherein the display panel includes a plurality of pixel blocks each including one or more of the pixels, and the plurality of pixel blocks includes a first pixel block and a second pixel block, the control method includes: controlling the display panel such that a refresh rate of a pixel in the second pixel block is lower than a refresh rate of a pixel in the first pixel block.

An electronic device according to one aspect of the present disclosure includes: a display device, wherein the display device includes: a display panel including a plurality of pixels; and a control unit that controls the display panel, the display panel includes a plurality of pixel blocks each including one or more of the pixels, the plurality of pixel blocks includes a first pixel block and a second pixel block, and the control unit controls the display panel such that a refresh rate of a pixel in the second pixel block is lower than a refresh rate of a pixel in the first pixel block.

### BRIEF DESCRIPTION OF DRAWINGS

FIG. 1 is a diagram illustrating an example of a schematic configuration of a display device according to an embodiment.

FIG. 2 is a diagram illustrating an example of control of a display panel.

FIG. 3 is a diagram illustrating an example of control of the display panel.

FIG. 4 is a diagram illustrating an example of control of the display panel.

FIG. 5 is a diagram illustrating an example of control of the display panel.

FIG. 6 is a diagram illustrating an example of control of the display panel.

FIG. 7 is a diagram schematically illustrating an example of luminance adjustment.

FIG. 8 is a diagram illustrating an example of processing executed in the display device (control method for the display panel).

FIG. 9 is a diagram illustrating an example of processing executed in the display device (control method for the display panel).

FIG. 10 is a diagram illustrating a comparative example.

FIG. 11 is a diagram illustrating the comparative example.

FIG. 12 is a diagram illustrating the comparative example.

FIG. 13 is a diagram illustrating the comparative example.

FIG. 14 is a diagram illustrating the comparative example.

FIG. 15 is a diagram illustrating an exemplary circuit configuration.

FIG. 16 is a diagram illustrating an example of control of pixel blocks by control circuits.

FIG. 17 is a diagram illustrating an example of the circuit operation.

FIG. 18 is a diagram illustrating an example of the circuit operation.

FIG. 19 is a diagram illustrating an example of the circuit operation.

FIG. 20 is a diagram illustrating an example of the circuit operation.

FIG. 21 is a diagram illustrating an example of the circuit operation.

FIG. 22 is a diagram illustrating an example of an electronic device.

FIG. 23 is a diagram illustrating an example of an electronic device.

### DESCRIPTION OF EMBODIMENTS

Hereinafter, embodiments of the present disclosure will be described in detail on the basis of the drawings. Note that in each of the following embodiments, the same elements are denoted by the same symbols, and redundant description will be omitted.

The present disclosure will be described in the following order of items.
0. Introduction
1. Embodiments
2. Application Examples
3. Exemplary Effects

### 0. Introduction

In a display device using an OLED or the like for a display panel, with an increase in the number of pixels and an increase in the frame rate, there are emerging issues of an increase in the power consumption and heat generation. When the power consumption increases, the available time of a product is reduced. In a head mounted display (HMD) worn on the head of a user, as represented by virtual reality (VR), heat generation can be a major issue. There is also an HMD incorporating a cooling fan or the like.

At least some of the issues as described above are addressed by the disclosed technology. A display panel is controlled (driven) in such a manner that the refresh rate varies between some pixel blocks and other pixel blocks among a plurality of pixel blocks included in the display panel. For example, by utilizing the fact that the field of view having a high-resolution is narrow in humans, the display panel is controlled such that only the refresh rate of pixel blocks in the vicinity of a detected field of view is increased while the refresh rate of the other pixel blocks is decreased. As the refresh rate of the other pixel blocks is decreased, the power consumption and heat generation can be suppressed.

### 1. Embodiments

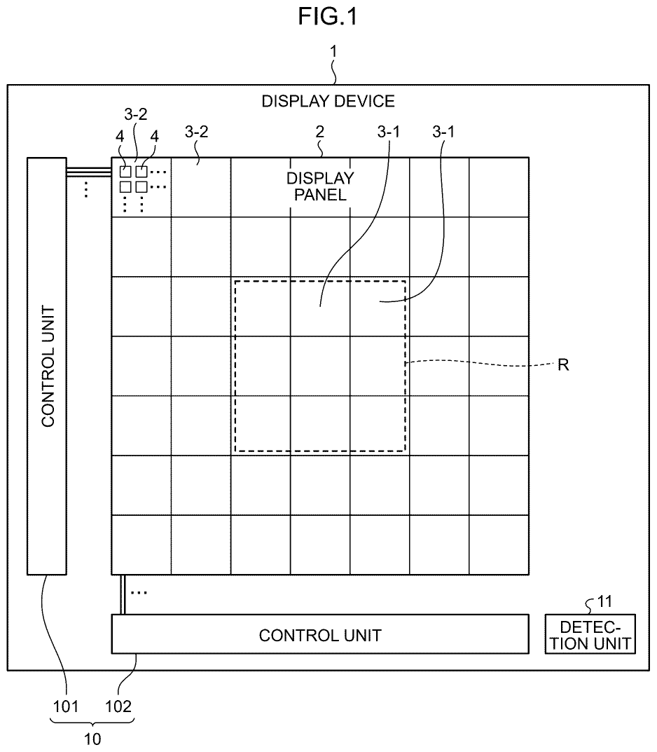

FIG. 1 is a diagram illustrating an example of the schematic configuration of a display device according to an embodiment. A display device 1 includes a display panel 2, a control unit 10, and a detection unit 11.

The display panel 2 includes a plurality of pixels 4. The plurality of pixels 4 is arranged in an array shape in a horizontal direction and a vertical direction. The display panel 2 can also be referred to as a pixel array unit. As described later, a pixel 4 includes a light emitting element and a drive circuit, and thus a pixel 4 can also be referred to as a pixel circuit.

In the present embodiment, the display panel 2 includes a plurality of pixel blocks 3 each including one or more pixels 4. Although details will be described later, the plurality of pixel blocks 3 includes two types of pixel blocks. A first pixel block is referred to as a pixel block 3-1 in the drawing. A second pixel block is referred to as a pixel block 3-2 in the drawing. In a case where they are not particularly distinguished from each other, they are simply referred to as pixel blocks 3. Note that, in the example illustrated in FIG. 1, each pixel block 3 includes a plurality of pixels 4.

The plurality of pixel blocks 3 is arranged in an array shape in the horizontal direction and the vertical direction of the display panel 2 (lateral direction and vertical direction and/or row direction and column direction). FIG. 1 illustrates 7×7 pixel blocks 3; however, the number of pixel blocks 3 is not limited to this example. For example, in a case where the display panel 2 having a viewing angle of 90 degrees in the vertical direction is divided by 10 degrees each, a structure in which nine pixel blocks 3 are arranged side by side in the vertical direction may be adopted. The same applies to the horizontal direction.

The control unit 10 controls light emission and extinction (no light emission) of each pixel 4 and controls luminance (light emission amount). Various known control methods may be used. In the example illustrated in FIG. 1, the control unit 10 includes a control unit 101 and a control unit 102.

The control unit 101 functions as, for example, a vertical driver that scans and drives pixels 4 corresponding to a display line in the horizontal direction. The control unit 101 is connected to the display panel 2 via a plurality of circuit lines. For example, one circuit line is connected to each of pixels 4 arranged in the horizontal direction. The control unit 101 selects a circuit line and supplies a control signal to corresponding pixels 4.

The control unit 102 functions as, for example, a horizontal driver that selects and drives pixels 4 corresponding to a display line in the vertical direction. The control unit 102 is connected to the display panel 2 via a plurality of circuit lines. For example, some circuit lines are connected to each of pixel blocks 3 arranged in the vertical direction, and some circuit lines are connected to each of pixels 4 arranged in the vertical direction. The control unit 102 selects a circuit line and supplies a control signal to a corresponding pixel block 3 or supplies a pixel signal or the like to a corresponding pixel 4. Note that the pixel 4 emits light with luminance corresponding to a pixel signal from the control unit 102.

The detection unit 11 detects the line of sight of the user of the display device 1. Various types of known line-of-sight detecting technology may be employed. For example, the eye portions of the user may be imaged with infrared light, and the line of sight of the user may be detected on the basis of the result. More specifically, the detection unit 11 detects a region in the display panel 2 located ahead of the line of sight of the user (viewed by the user). This region is referred to as a region R in the drawings.

The region R can typically be located at the center of display panel 2 and in the vicinity thereof. This is because in the HMD or the like, the center of the field of view of the user is often located at the center of the display panel 2 or in the vicinity thereof. However, as a matter of course, the region R changes as the line of sight of the user changes and can be any region in the display panel 2.

The control unit 10 selects pixel blocks 3-1 and pixel blocks 3-2 from the plurality of pixel blocks 3 on the basis of a detection result of the detection unit 11. Specifically, the control unit 10 selects, as the pixel blocks 3-1, pixel blocks 3 located in the region R from among the plurality of pixel blocks 3 and selects the remaining pixel blocks 3 as the pixel blocks 3-2. In the example illustrated in FIG. 1, the pixel blocks 3-1 are located closer to the center of the display panel 2 than the pixel blocks 3-2 are.

In the present embodiment, the control unit 10 controls the display panel 2 such that the refresh rate of pixels 4 in a pixel block 3-2 is lower than the refresh rate of pixels 4 in a pixel block 3-1. The refresh of a pixel 4 includes writing of data to the pixel 4 (setting of luminance by a pixel signal), light emission in the pixel 4 (light emission at a set luminance), and extinction of light in the pixel 4. Initialization and the like of the pixel 4 may also be included in the refresh of the pixel 4.

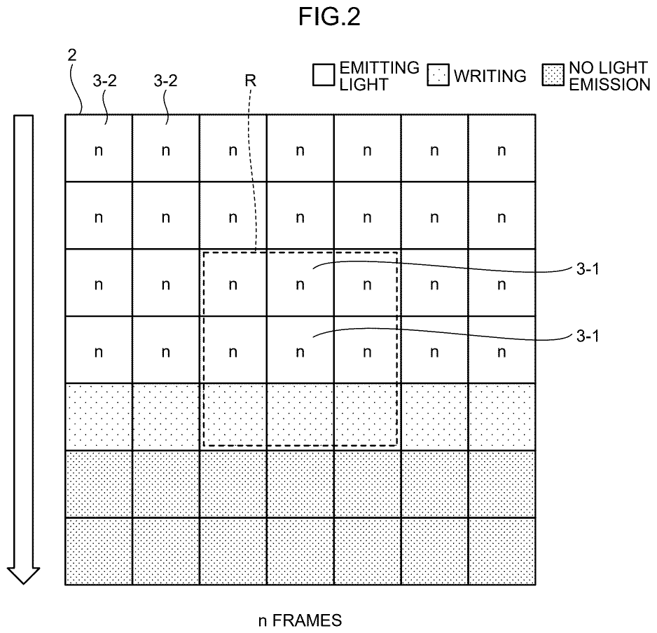

The control unit 10 controls the display panel 2 such that the pixels 4 in the pixel blocks 3-2 continue to emit light without being refreshed while the pixels 4 in the pixel block 3-1 are refreshed repeatedly twice or more. An example will be described with reference to FIGS. 2 to 6.

FIGS. 2 to 6 are diagrams illustrating an example of control of the display panel. As indicated by the hollow arrow, the pixels 4 (FIG. 1) in each pixel block 3 can be sequentially driven row by row. Note that, in the following description, pixels 4 in a pixel block 3 may also be simply referred to as a pixel block 3.

FIG. 2 schematically illustrates the state of each pixel block 3 of an n-th frame (n is an integer greater than or equal to 1). All the pixel blocks 3 are refreshed. According to the sequential driving performed row by row, in this example, pixel blocks 3 of the first to fourth rows emit light, data is written in the pixel blocks 3 of the fifth row, and the pixel blocks 3 of the sixth and seventh rows emit no light.

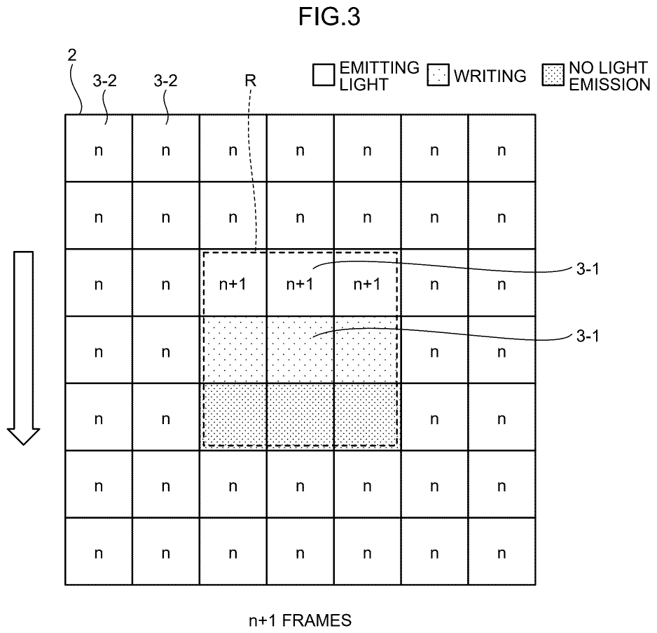

FIG. 3 schematically illustrates the state of each pixel block 3 in an (n+1)th frame. Only the pixel block 3-1 are refreshed, and an image of the (n+1)th frame is displayed. The pixel blocks 3-2 continue to emit light without being refreshed and still display an image of the n-th frame. Note that the image may be rephrased with a video as appropriate as long as there is no contradiction.

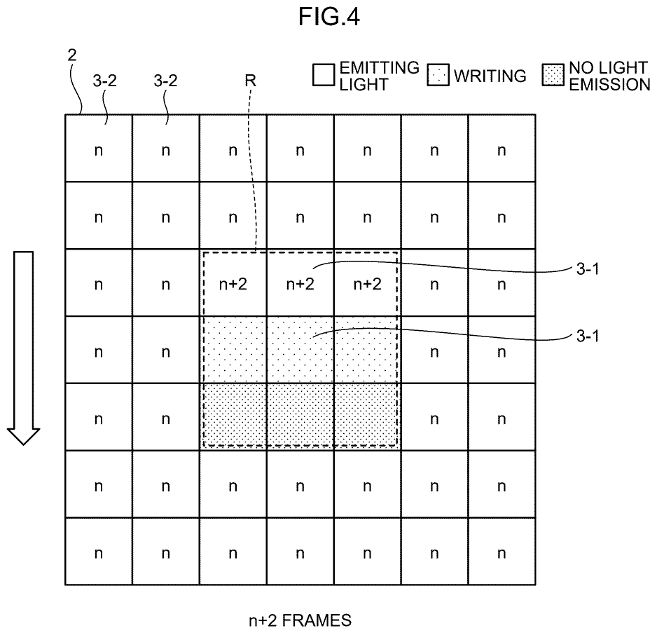

FIG. 4 schematically illustrates the state of each pixel block 3 in an (n+2)th frame. Only the pixel blocks 3-1 are refreshed to display an image of the (n+2)th frame. The pixel blocks 3-2 continue to emit light without being refreshed and still display the image of the n-th frame.

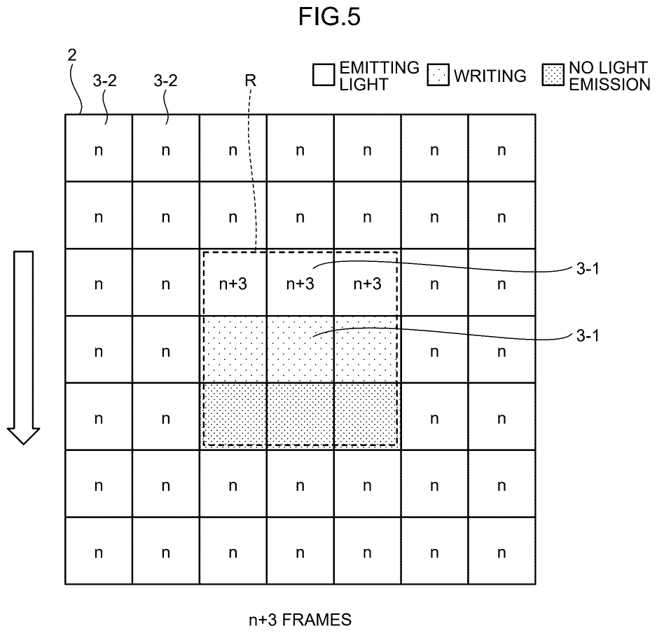

FIG. 5 schematically illustrates the state of each pixel block 3 in an (n+3)th frame. Only the pixel blocks 3-1 are refreshed to display an image of an (n+3)th frame. The pixel blocks 3-2 continue to emit light without being refreshed and still display the image of the n-th frame.

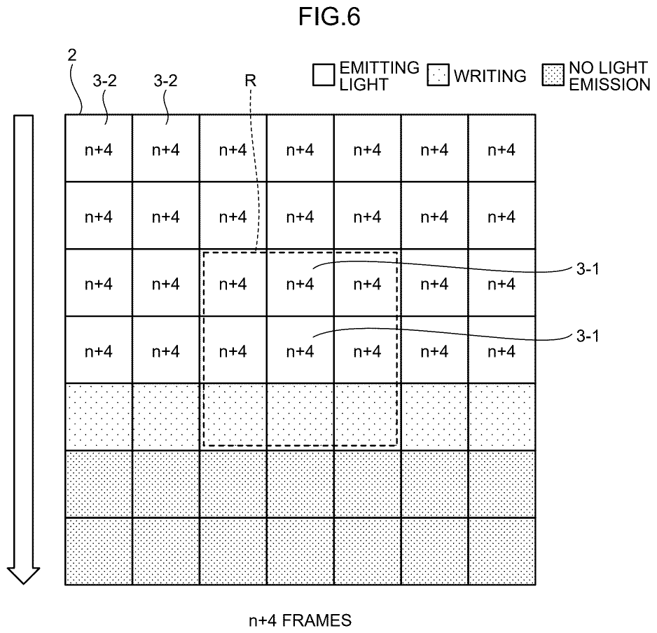

FIG. 6 schematically illustrates the state of each pixel block 3 in an (n+4)th frame. Similarly to the n-th frame (FIG. 2), all the pixel blocks 3, namely, both the pixel blocks 3-1 and the pixel blocks 3-2 are refreshed to display an image of the (n+4)th frame.

By repeating the above operation, the display panel 2 is controlled such that the refresh rate of the pixel block 3-2 is lower than the refresh rate of pixel block 3-1. Note that the position of the region R in the display panel 2, namely, selection of the pixel blocks 3-1 and the pixel blocks 3-2 may be modified as appropriate depending on the detection result of the detection unit 11 (FIG. 1).

### Example of Luminance Adjustment

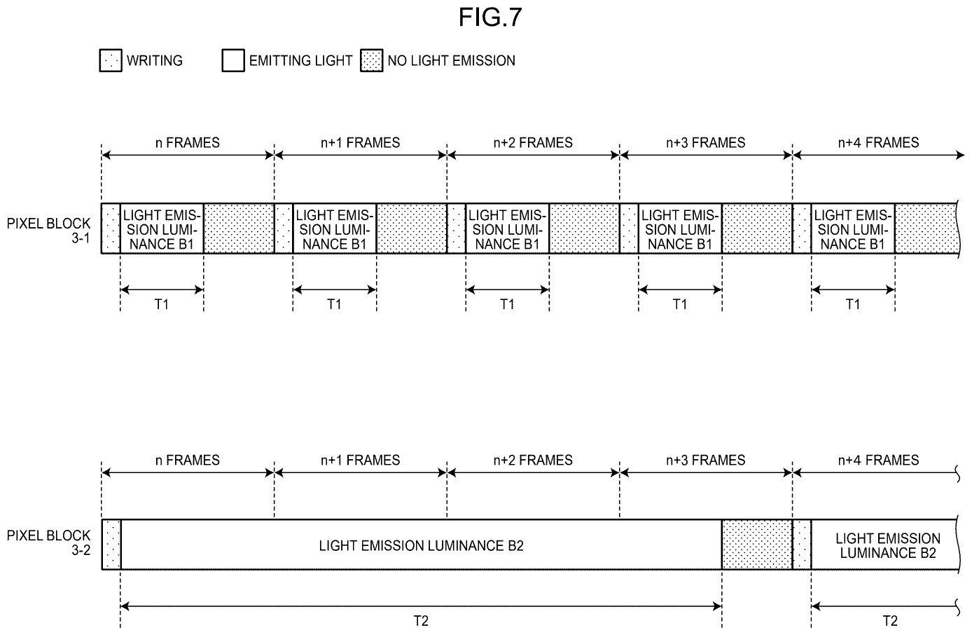

In one embodiment, the control unit 10 may control the display panel 2 such that the light emission luminance (luminance at the time of light emission) of the pixel blocks 3-1 is different from the light emission luminance of the pixel blocks 3-2. This will be described with reference to FIG. 7.

FIG. 7 is a diagram schematically illustrating an example of luminance adjustment. A pixel block 3-1 is refreshed frame by frame. The light emission period of the pixel block 3-1 in each frame is referred to as a light emission period T1. The light emission luminance during the light emission period T1 is referred to as light emission luminance B1. A pixel block 3-2 is refreshed only once in a plurality of frames, in this example four frames. The light emission period of the pixel block 3-2 over four frames is referred to as a light emission period T2. The light emission luminance during the light emission period T2 is referred to as light emission luminance B2.

When observed over the entire four frames, the light emission period (T1×4) of the pixel block 3-1 and the light emission period T2 of the pixel block 3-2 are different from each other. Specifically, the light emission period (T1×4) of the pixel block 3-1 is shorter than the light emission period T2 of the pixel block 3-2.

In one embodiment, the control unit 10 may control the display panel 2 such that the light emission luminance B1 of the pixel blocks 3-1 is larger than the light emission luminance B2 of the pixel blocks 3-2. More specifically, the control unit 10 may control the light emission luminance B1 of the pixel blocks 3-1 and the light emission luminance B2 of the pixel blocks 3-2 on the basis of the ratio between the light emission period T1 of the pixel blocks 3-1 and the light emission period T2 of the pixel blocks 3-2. For example, as expressed in the following equation (1), the light emission luminance B1 and the light emission luminance B2 may be set such that a value obtained by multiplying the light emission luminance B1 of the pixel blocks 3-1 and the light emission period (T1×4) of the pixel blocks 3-1 matches (approaches) a value obtained by multiplying the light emission luminance B2 of the pixel blocks 3-2 and the light emission period T2 of the pixel blocks 3-2. As a result, the luminance of the pixel blocks 3-1 and the luminance of the pixel blocks 3-2 over the entire four frames can be balanced (for example, matched).

$$B 1 \times ( T 1 \times 4 ) = B 2 \times T 2 \qquad ( 1 )$$

Note that the control of the light emission luminance B1 is performed by adjusting a pixel signal supplied from the control unit 10 to pixels 4 in a pixel block 3-1. The control of the light emission luminance B2 is performed by adjusting a pixel signal supplied from the control unit 10 to pixels 4 in a pixel block 3-2.

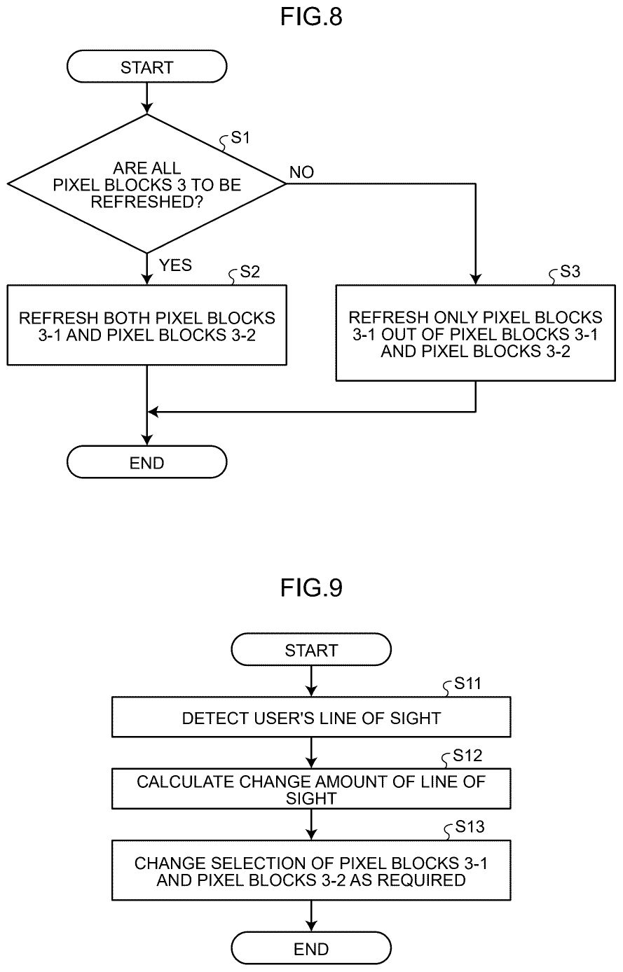

FIGS. 8 and 9 are diagrams illustrating an example of processing executed in the display device (control method for the display panel). Overlapping description will be omitted as appropriate.

FIG. 8 illustrates an example of processing executed in one frame. In step S1, the control unit 10 determines whether or not to refresh all the pixel blocks 3. For example, in the example of FIGS. 2 to 7 described above, in a case where the frame of this flow is the n-th frame or the (n+4)th frame, it is determined to refresh all the pixel blocks 3. If all the pixel blocks 3 are refreshed (step S1: Yes), the processing proceeds to step S2. If not (step S1: No), the processing proceeds to step S3. In step S2, the control unit 10 refreshes both the pixel blocks 3-1 and the pixel blocks 3-2, namely, all the pixel blocks 3. In step S3, the control unit 10 refreshes only the pixel blocks 3-1 out of the pixel blocks 3-1 and the pixel blocks 3-2. After the processing of step S2 or step S3 is completed, the processing of the flowchart ends. This processing is repeatedly executed for each frame, during which the processing of step S3 is performed, whereby the refresh rate of the pixel blocks 3-1 increases and the refresh rate of the pixel blocks 3-2 decreases.

FIG. 9 illustrates an example of processing for selecting the pixel blocks 3-1 and the pixel blocks 3-2 from the plurality of pixel blocks 3. In step S11, the detection unit 11 detects the line of sight of the user of the display device 1. In step S12, the control unit 10 calculates a change amount in the line of sight. For example, an amount indicating a difference (shift or the like) between the region R in the display panel 2 indicated by a previous detection result from the detection unit 11 and the region R in the display panel 2 indicated by the current detection result from the detection unit 11 in step S11 is calculated as the change amount in the line of sight. In step S13, the control unit 10 changes the selection of the pixel blocks 3-1 and the pixel blocks 3-2 as necessary. For example, in a case where the change amount in the line of sight calculated in step S12 described above is large and there occurs such a circumstance that the selected pixel blocks 3-1 do not fit within the region R, the control unit 10 changes the selection of the pixel blocks 3-1 and the pixel blocks 3-2. Specifically, among the plurality of pixel blocks 3, the control unit 10 selects, as the pixel blocks 3-1, pixel blocks 3 located in the region R indicated by the current detection result from the detection unit 11 in step S11 and selects the remaining pixel blocks 3 as the pixel blocks 3-2. After the processing of step S13 is completed, the processing of the flowchart ends. The processing of this flowchart is repeatedly executed at desired timing (for example, frame by frame).

According to the display device 1 described above, the display panel 2 is controlled such that the refresh rate of the pixel blocks 3-2 is lower than the refresh rate of pixel blocks 3-1. As the refresh rate of the pixel blocks 3-2 decreases, power consumption and heat generation can be suppressed. A comparative example will also be described.

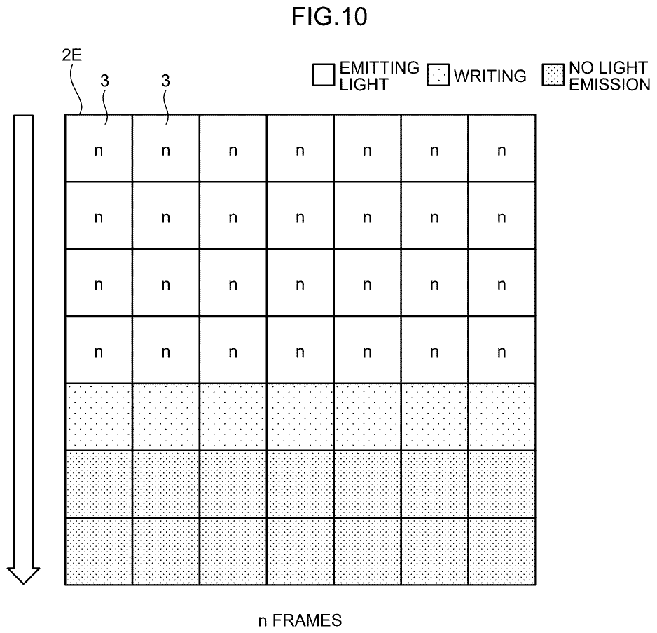

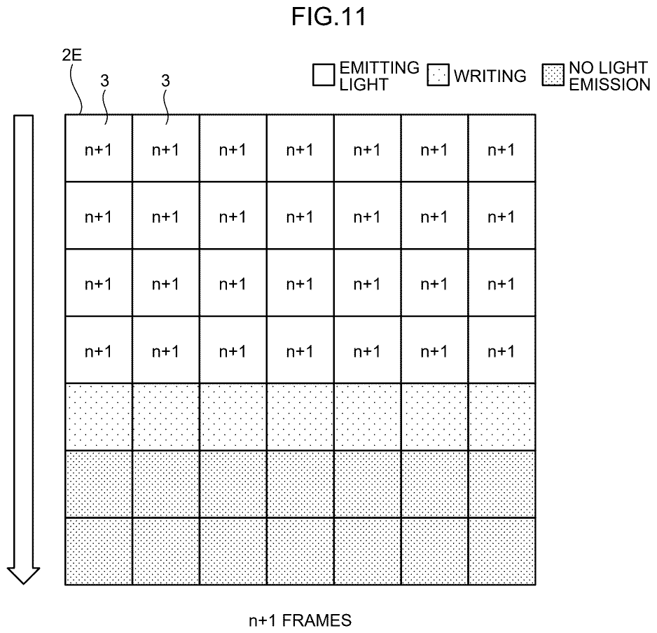

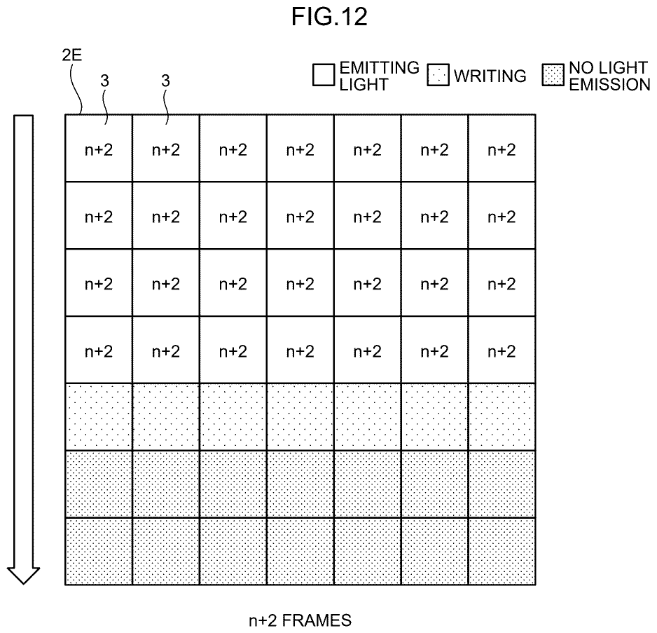

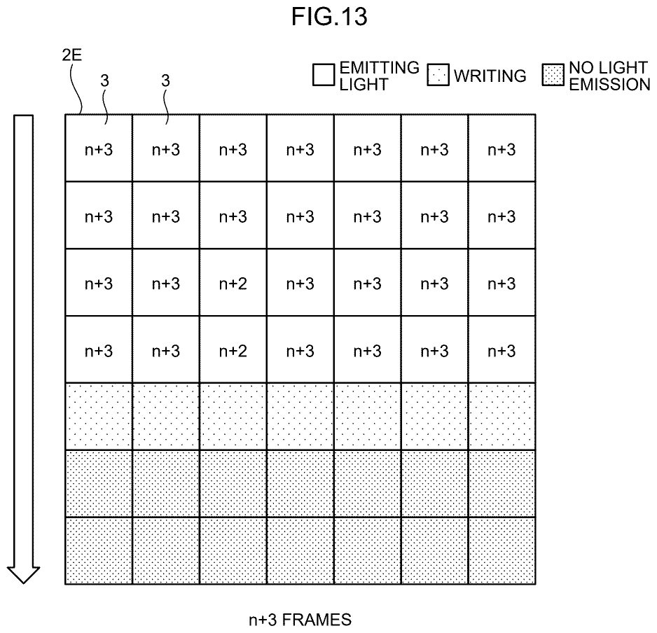

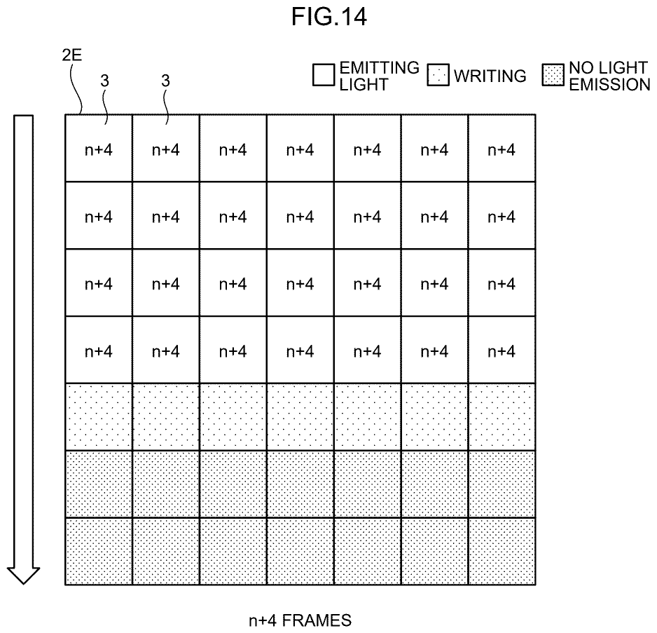

FIGS. 10 to 14 are diagrams illustrating a comparative example. A display panel 2E according to the comparative example is controlled such that all pixel blocks 3 are refreshed at a high refresh rate. As illustrated in FIG. 10, in the n-th frame, all the pixel blocks 3 are refreshed, and an image of the n-th frame is displayed. As illustrated in FIG. 11, also in the (n+1)th frame, all the pixel blocks 3 are refreshed, and an image of the (n+1)th frame is displayed. As illustrated in FIG. 12, also in the (n+2)th frame, all the pixel blocks 3 are refreshed, and an image of the (n+2)th frame is displayed. As illustrated in FIG. 13, also in the (n+3)th frame, all the pixel blocks 3 are refreshed, and an image of the (n+3)th frame is displayed. As illustrated in FIG. 14, also in the (n+4)th frame, all the pixel blocks 3 are refreshed, and an image of the (n+4)th frame is displayed.

In the above-described comparative example, as the number of pixels or the frame rate increases, the number of pixels to which data is written per unit time increases, the power consumption increases, and the temperature of the display panel 2E increases due to heat generation. Such issues are addressed by the display device 1 according to the embodiment.

Note that there is also known technology of selectively using image data of high resolution and low resolution such as foveated rendering; however, there is no change in controlling (driving) the entire plane of the display panel 2. Compared with the display device 1 according to the embodiment, the effect of suppressing power consumption and heat generation is limited. In addition, a method of using a plurality of display panels having different refresh rates is also conceivable; however, using the plurality of display panels increases the number of components as well as the cost. According to the display device 1 of the embodiment, it suffices to use one display panel 2, such an issue can also be addressed.

### Example of Circuit Configuration

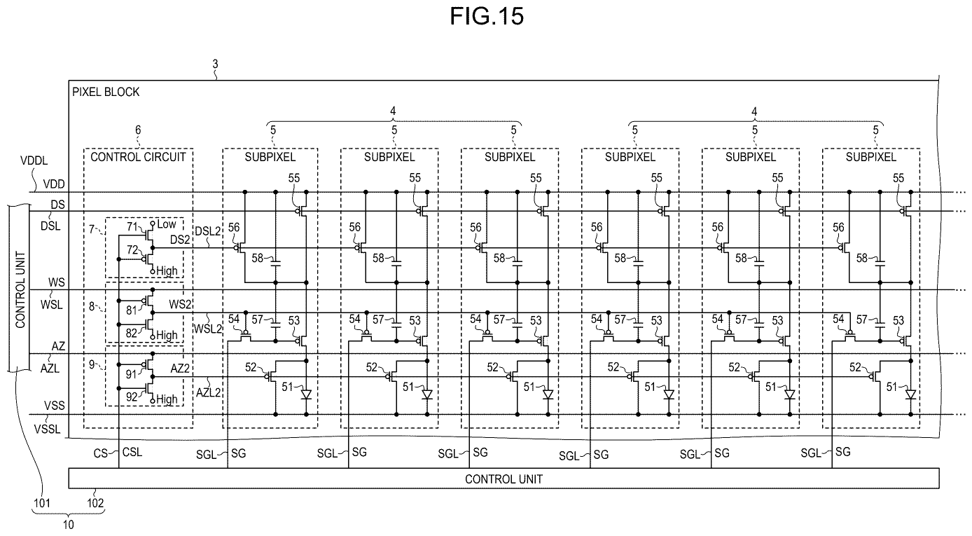

An exemplary circuit configuration for enabling control of the display panel 2 as described above will be described with reference to FIG. 15.

FIG. 15 is a diagram illustrating an exemplary circuit configuration. A pixel block 3 includes a control circuit 6 in addition to pixels 4 described above.

Examples of circuit lines extending in the pixel block 3 from the outside of the pixel block 3 include a power supply line VDDL, a control line DSL, a control line WSL, a control line AZL, a power supply line VSSL, a control line CSL, and a signal line SGL. The power supply line VDDL is connected to each of pixel blocks 3 arranged in the horizontal direction and supplies a power supply voltage VDD. The power supply line VSSL is connected to each of pixel blocks 3 arranged in the horizontal direction and supplies a reference voltage VSS. The control line DSL, the control line WSL, and the control line AZL are connected to each of pixel blocks 3 arranged in the horizontal direction and supply a control signal from the control unit 10 to the pixel blocks 3. The control signals supplied by the control line DSL, the control line WSL, and the control line AZL are referred to as a control signal DS, a control signal WS, and a control signal AZ, respectively. The control line DSL is a circuit line for supplying the control signal DS from the control unit 10 to a control terminal of a transistor 55 described later. The control line WSL is a circuit line for supplying the control signal WS from the control unit 10 to a transistor 54 described later. The control line AZL is a circuit line for supplying the control signal AZ from the control unit 10 to a control terminal of a transistor 52 described later. The control line CSL and the signal line SGL are connected to each of pixel blocks 3 and supply a control signal from the control unit 10 to the pixel blocks 3. The control signals supplied by the control line CSL and the signal line SGL are referred to as a control signal CS and a control signal SG. An example of the control signal SG is a pixel signal.

A pixel 4 includes a plurality of subpixels 5, in this example three subpixels 5. Each of the three subpixels 5 is configured to emit light of different colors. Examples of the light include red light (R), green light (G), and blue light (B).

A subpixel 5 includes a light emitting element 51. The light emitting element 51 is a current-driven type light emitting element that emits light having luminance corresponding to the magnitude of the current flowing through the light emitting element. An example of the light emitting element 51 is an OLED or the like, and, in this example, description is given on a premise that the light emitting element 51 is an OLED.

The subpixel 5 further includes a drive circuit. The drive circuit includes, for example, a transistor and a capacitor. It is based on a premise that the transistor is a MOSFET. The gate of the transistor is also referred to as a control terminal. The drain and the source of the transistor are also referred to as current terminals. Note that a transistor being connected to a certain element may be understood to mean that a current terminal of the transistor is connected to the element. A transistor being connected between two elements may be understood to mean that one current terminal of the transistor is connected to one of the elements and that the other current terminal is connected to the other element. A transistor being ON may be understood to mean that the current terminals of the transistor are in a conductive state. A transistor being OFF may be understood to mean that the current terminals of the transistor are in a non-conductive state.

Specifically, FIG. 15 illustrates a transistor 52, a transistor 53, a transistor 54, a transistor 55, a transistor 56, a capacitor 57, and a capacitor 58 as exemplary components of a drive circuit. The transistor 52 is an initialization transistor that is connected in parallel to the light emitting element 51 and initializes the anode voltage of the light emitting element 51. The transistor 53 is a drive transistor for supplying a current corresponding to a pixel signal to the light emitting element 51. The transistor 54 is a sampling transistor for sampling the pixel signal. The transistor 55 is a light emission controlling transistor that is connected between the transistor 53 and the power supply line VDDL and controls light emission and extinction of the light emitting element 51. The transistor 56 is a second light emission controlling transistor connected in parallel to the transistor 55. The capacitor 57 is a holding capacitor that holds a voltage corresponding to the control signal SG. The capacitor 58 is an auxiliary capacitor that suppresses fluctuations in the potential at a current terminal of the transistor 53 at the time of voltage writing.

A more specific connection relationship will be described. The anode of the light emitting element 51 is connected to the transistor 53. The cathode of the light emitting element 51 is connected to the power supply line VSSL. The transistor 52 is connected between the anode of the light emitting element 51 and the power supply line VSSL. The control terminal of the transistor 52 is connected to the control circuit 6. The transistor 53 is connected between the anode of the light emitting element 51 and the transistor 55. The control terminal of the transistor 53 is connected to the transistor 54 and the capacitor 57. The transistor 54 is connected between the control terminal of the transistor 53 and a signal line SGL. The control terminal of the transistor 54 is connected to the control circuit 6. The transistor 55 is connected between the transistor 53 and the power supply line VDDL. The control terminal of the transistor 55 is connected to the control line DSL. The transistor 56 is connected between the transistor 53 and the power supply line VDDL. The control terminal of the transistor 56 is connected to the control circuit 6. The capacitor 57 is connected to the control terminal of the transistor 53 and a current terminal of the transistor 53 (current terminal on the transistor 55 side). The capacitor 58 is connected between the current terminal of the transistor 53 (current terminal on the transistor 55 side) and the power supply line VDDL.

With the above circuit configuration, it is made possible to cause the light emitting element 51 to emit light with luminance corresponding to a pixel signal (an example of the control signal SG) from the signal line SGL and to turn off the light. For example, when the transistor 54 is ON, a voltage corresponding to the voltage of the pixel signal from the signal line SGL serves as a voltage between both terminals of the capacitor 57 and is held. When at least one of the transistor 55 and the transistor 56 is ON, the transistor 53 can supply the current corresponding to the voltage between both terminals of the capacitor 57 to the light emitting element 51. The light emitting element 51 can emit light with luminance corresponding to the pixel signal. When the transistor 52 is ON, the voltage at the anode of the light emitting element 51 is initialized to the voltage VSS of the power supply line VSSL. More specific operations shall be understood by those skilled in the art with an access to the circuit diagram of FIG. 15. See, for an example, Patent Literature 2.

The control circuit 6 is connected to the pixels 4 in the pixel block 3 including the control circuit 6 (corresponding pixel block 3), more specifically, to each subpixel 5 in the pixels 4. The control circuit 6 causes the corresponding pixel block 3 as a pixel block 3-1 or a pixel block 3-2 on the basis of the control signal CS from the control unit 10. Specifically, the control circuit 6 is connected between the pixels 4 and the control line WSL, the control line AZL, and the control line CSL and controls some transistors in the pixels 4. Specifically, in the example illustrated in FIG. 15, the control circuit 6 includes a switch circuit 7, a switch circuit 8, and a switch circuit 9.

The switch circuit 7 is a first switch circuit and is connected to the control terminal of the transistor 56. The switch circuit 7 includes a transistor 71 and a transistor 72. The transistor 71 and the transistor 72 are cascade-connected to each other. In this example, the transistor 71 is an n-type MOSFET, and the transistor 72 is a p-type MOSFET. One current terminal of the transistor 71 is connected to a low voltage power supply (Low), and the other current terminal is connected to one current terminal of the transistor 72. The other current terminal of the transistor 72 is connected to a high voltage power supply (High).

The control terminals of the transistor 71 and the transistor 72 correspond to an input terminal of the switch circuit 7 and are connected to the control line CSL. The connection point of the transistor 71 and the transistor 72 corresponds to an output terminal of the switch circuit 7 and is connected to the control terminal of the transistor 56.

A signal output from the output terminal of the switch circuit 7 is referred to as a control signal DS2. Furthermore, a circuit line connecting the output terminal of the switch circuit 7 and the control terminal of the transistor 56 is referred to as a control line DSL2. A control signal DS2 from the control line DSL2 is supplied to the control terminal of the transistor 56.

The switch circuit 8 is a second switch circuit and is connected between the control line WSL and the control terminal of the transistor 54. The switch circuit 8 includes a transistor 81 and a transistor 82. The transistor 81 and the transistor 82 are cascade-connected to each other. In this example, the transistor 81 is a p-type MOSFET, and the transistor 82 is an n-type MOSFET. One current terminal of the transistor 81 is connected to the control line WSL, and the other current terminal is connected to one current terminal of the transistor 82. The other current terminal of the transistor 82 is connected to the high-voltage power supply.

The control terminals of the transistor 81 and the transistor 82 correspond to an input terminal of the switch circuit 8 and are connected to the control line CSL. The connection point of the transistor 81 and the transistor 82 corresponds to an output terminal of the switch circuit 8 and is connected to the control terminal of the transistor 54.

A signal output from the output terminal of the switch circuit 8 is referred to as a control signal WS2. Furthermore, a circuit line connecting the output terminal of the switch circuit 8 and the control terminal of the transistor 54 is referred to as a control line WSL2. A control signal WS2 from the control line WSL2 is supplied to the control terminal of the transistor 54. Depending on the state of the switch circuit 8, the control signal WS from the control line WSL becomes the control signal WS2.

The switch circuit 9 is a third switch circuit and is connected between the control line AZL and the control terminal of the transistor 52. The switch circuit 9 includes a transistor 91 and a transistor 92. The transistor 91 and the transistor 92 are cascade-connected to each other. In this example, the transistor 91 is a p-type MOSFET, and the transistor 92 is an n-type MOSFET. One current terminal of the transistor 91 is connected to the control line AZL, and the other current terminal is connected to one current terminal of the transistor 92. The other current terminal of the transistor 92 is connected to the high-voltage power supply.

The control terminals of the transistor 91 and the transistor 92 correspond to an input terminal of the switch circuit 9 and are connected to the control line CSL. The connection point of the transistor 91 and the transistor 92 corresponds to an output terminal of the switch circuit 9 and is connected to the control terminal of the transistor 52.

A signal output from the output terminal of the switch circuit 9 is referred to as a control signal AZ2. Furthermore, a circuit line connecting the output terminal of the switch circuit 9 and the control terminal of the transistor 52 is referred to as a control line AZL2. A control signal AZ2 from the control line AZL2 is supplied to the control terminal of the transistor 52. Depending on the state of the switch circuit 9, the control signal AZ from the control line AZL becomes the control signal AZ2.

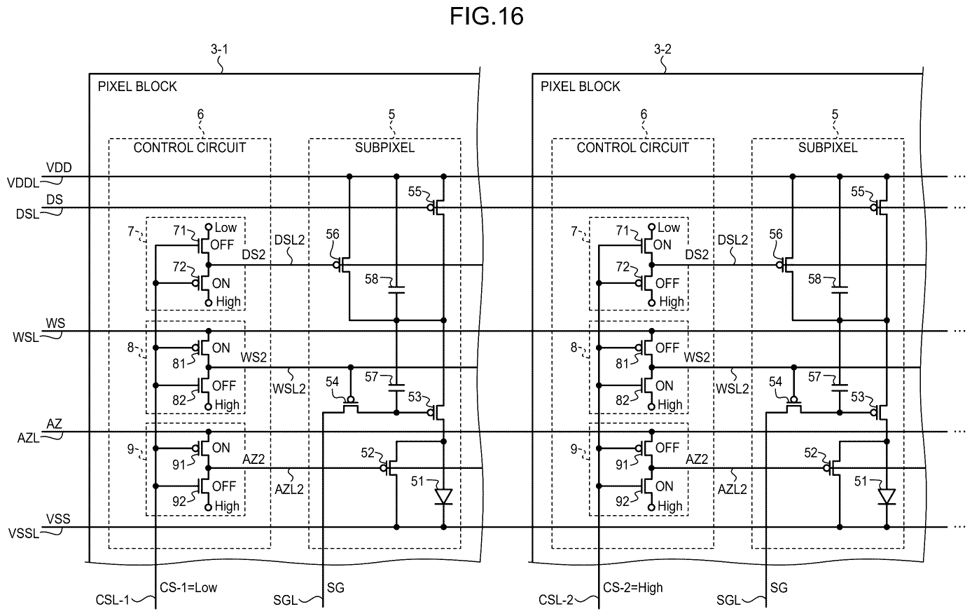

By adjusting the control signal CS supplied to the control circuit 6 included in each of the pixel blocks 3, each of the pixel blocks 3 can be caused to operate as either a pixel block 3-1 or a pixel block 3-2. This will be described with reference to FIG. 16.

FIG. 16 is a diagram illustrating an example of control of pixel blocks by control circuits. One pixel block 3-1 and one pixel block 3-2 are illustrated. Although details will be described later, in a case where the control circuit 6 causes a pixel block 3 including the control circuit 6 to operate as a pixel block 3-1, the switch circuit 7 turns off the transistor 56, the switch circuit 7 supplies the control signal WS from the control unit 10 to the control terminal of the transistor 54, and the switch circuit 9 supplies the control signal AZ from the control unit 10 to the control terminal of the transistor 52. In a case where the control circuit 6 causes the pixel block 3 including the control circuit 6 as a pixel block 3-2, the switch circuit 7 turns on the transistor 56, the switch circuit 8 turns off the transistor 54, and the switch circuit 9 turns off the transistor 52.

The control line CSL connected to the pixel block 3-1 is referred to as a control line CSL-1. The control signal CS supplied from the control line CSL-1 to the pixel block 3-1 is referred to as a control signal CS-1. The control line CSL connected to the pixel block 3-2 is referred to as a control line CSL-2. The control signal CS supplied from the control line CSL-2 to the pixel block 3-2 is referred to as a control signal CS-2.

The control unit 10 supplies the control signal CS-1 to the pixel block 3 to cause the pixel block 3 to operate as a pixel block 3-1. The control unit 10 supplies the control signal CS-2 to the pixel block 3 to cause the pixel block 3 to operate as a pixel block 3-2. In this example, the control signal CS-1 is a low voltage signal (Low). The control signal CS-2 is a high voltage signal (High).

In the pixel block 3-1, the transistor 71 of the switch circuit 7 of the control circuit 6 is OFF, and the transistor 72 is ON. The control signal DS2 is a high voltage signal. The transistor 81 of the switch circuit 8 is ON, and the transistor 82 is OFF. The control signal WS2 is the control signal WS. The transistor 91 of the switch circuit 7 of the control circuit 6 is ON, and the transistor 92 is OFF. The control signal AZ2 is the control signal AZ.

In the pixel block 3-2, the transistor 71 of the switch circuit 7 is ON, and the transistor 72 is OFF. The control signal DS2 is a low voltage signal. The transistor 81 of the switch circuit 8 is OFF, and the transistor 82 is ON. The control line WSL2 is a high voltage signal. The transistor 91 of the switch circuit 9 is OFF, and the transistor 92 is ON. The control line AZL2 is a high voltage signal.

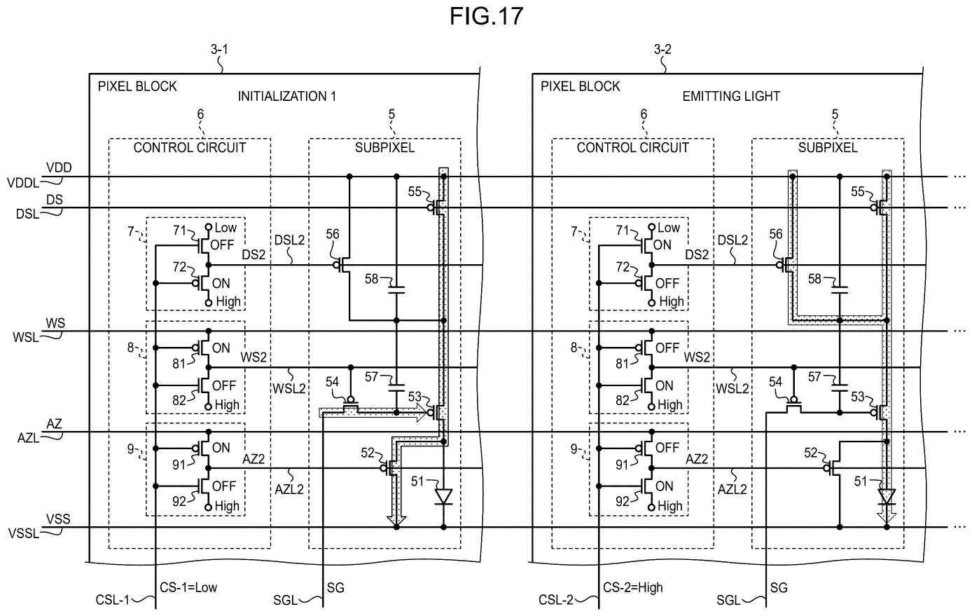

FIGS. 17 to 21 are diagrams illustrating an example of circuit operation. A site of operation to be mainly noted in the circuit is indicated by hatching.

### <Initialization>

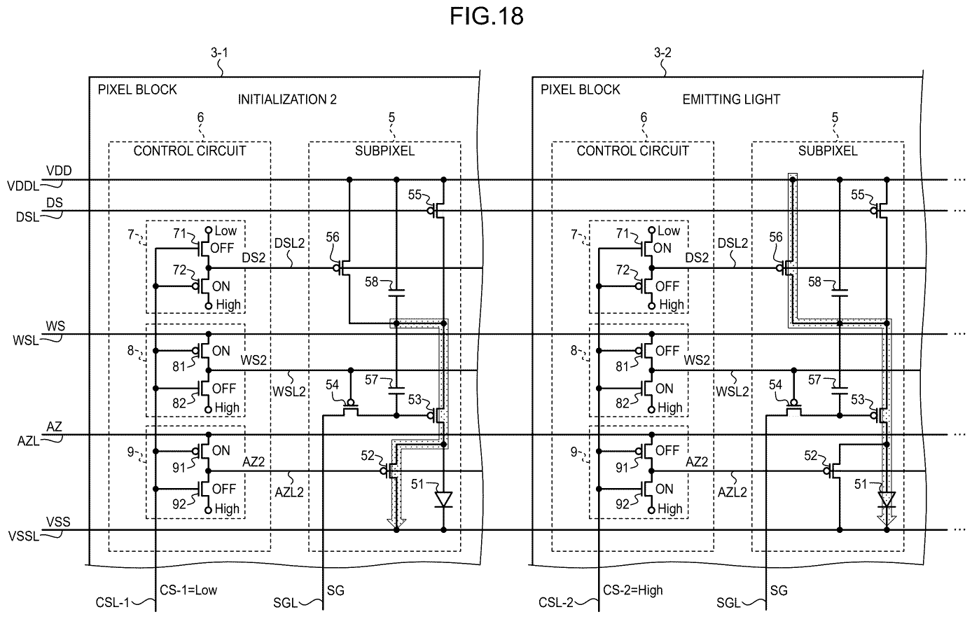

FIGS. 17 and 18 illustrate operations related to initialization. Hereinafter, initialization of the voltage of the transistor 53 (initialization 1) and holding of a threshold voltage of the transistor 53 (initialization 2) will be described in this order.

### <Initialization 1>

As illustrated in FIG. 17, the control signal DS, the control signal WS, and the control signal AZ are low voltage signals (Low). The control signal SG is a reference voltage signal for initialization. In both the pixel block 3-1 and the pixel block 3-2, the transistor 55 is ON.

In the pixel block 3-1, the control signal DS2 is a high voltage signal. The transistor 56 is OFF. The control signal WS2 is the control signal WS, namely, a low voltage signal. The transistor 54 is ON. The control signal AZ2 is the control signal AZ, namely, a low voltage signal. The transistor 52 is ON. As a result, the voltage of the control terminal of the transistor 53 is initialized to the voltage of the control signal SG (reference voltage), and the voltage of the current terminal of the transistor 53 (current terminal on the transistor 55 side) is initialized to the power supply voltage VDD.

In the pixel block 3-2, the control signal DS2 is a low voltage signal. The transistor 56 is ON. The control signal WS2 is a high voltage signal. The transistor 54 is OFF. The control signal AZ2 is a high voltage signal. The transistor 52 is OFF. The current from the power supply line VDDL is supplied to the light emitting element 51 via the transistor 55, the transistor 56, and the transistor 53. The light emitting element 51 emits light.

### <Initialization 2>

As illustrated in FIG. 18, the control signal DS and the control signal WS are high voltage signals (High), and the control signal AZ is a low voltage signal. In both the pixel block 3-1 and the pixel block 3-2, the transistor 55 is OFF. The control signal SG is a pixel signal.

In the pixel block 3-1, the control signal DS2 is a high voltage signal. The transistor 56 is OFF. The control signal WS2 is the control signal WS, namely, a high voltage signal. The transistor 54 is OFF. The control signal AZ2 is the control signal AZ, namely, a low voltage signal. The transistor 52 is ON. The voltage between the control terminal and a current terminal (current terminal on the transistor 55 side) of the transistor 53 converges to the threshold voltage of the transistor 53, and this voltage is held by the capacitor 57. The initialization is completed.

In the pixel block 3-2, the control signal DS2 is a low voltage signal. The transistor 56 is ON. The control signal WS2 is a high voltage signal. The transistor 54 is OFF. The control signal AZ2 is a high voltage signal. The transistor 52 is OFF. The current from the power supply line VDDL is supplied to the light emitting element 51 via the transistor 56 and the transistor 53. The light emitting element 51 still emits light.

### <Writing>

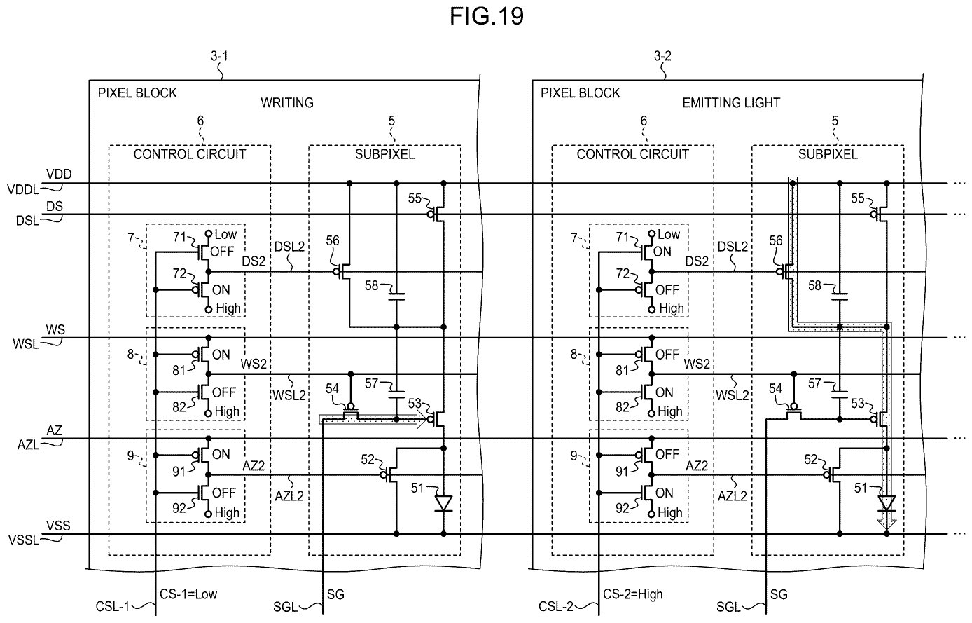

FIG. 19 illustrates an operation related to data writing in the pixel block 3-1. The control signal DS is a high voltage signal, and the control signal WS and the control signal AZ are low voltage signals. In both the pixel block 3-1 and the pixel block 3-2, the transistor 55 is OFF.

In the pixel block 3-1, the control signal DS2 is a high voltage signal. The transistor 56 is OFF. The control signal WS2 is the control signal WS, namely, a low voltage signal. The transistor 54 is ON. The control signal AZ2 is the control signal AZ, namely, a low voltage signal. The transistor 52 is ON. The control signal SG from the signal line SGL, namely, a pixel signal is written.

In the pixel block 3-2, the control signal DS2 is a low voltage signal. The transistor 56 is ON. The control signal WS2 is a high voltage signal. The transistor 54 is OFF. The control signal AZ2 is a high voltage signal. The transistor 52 is OFF. The current from the power supply line VDDL is supplied to the light emitting element 51 via the transistor 56 and the transistor 53. The light emitting element 51 still emits light.

### <Light Emission>

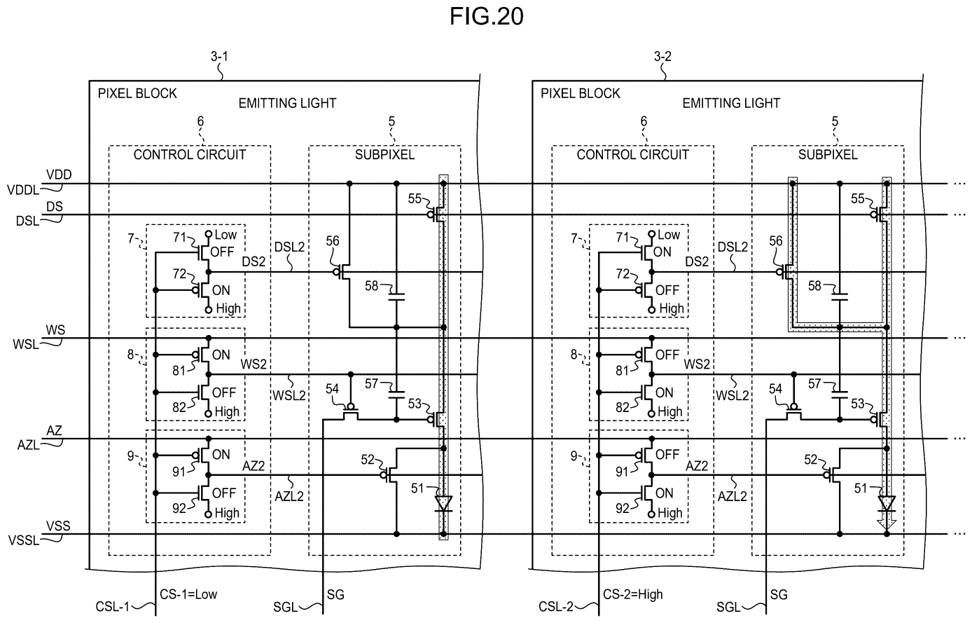

FIG. 20 illustrates an operation related to light emission. The control signal DS is a low voltage signal, and the control signal WS and the control signal AZ are high voltage signals. In both the pixel block 3-1 and the pixel block 3-2, the transistor 55 is ON.

In the pixel block 3-1, the control signal DS2 is a high voltage signal. The transistor 56 is OFF. The control signal WS2 is the control signal WS, namely, a high voltage signal. The transistor 54 is OFF. The control signal AZ2 is the control signal AZ, namely, a high voltage signal. The transistor 52 is OFF. The current from the power supply line VDDL is supplied to the light emitting element 51 via the transistor 55 and the transistor 53. The light emitting element 51 emits light.

In the pixel block 3-2, the control signal DS2 is a low voltage signal. The transistor 56 is ON. The control signal WS2 is a high voltage signal. The transistor 54 is OFF. The control signal AZ2 is a high voltage signal. The transistor 52 is OFF. The current from the power supply line VDDL is supplied to the light emitting element 51 via the transistor 55, the transistor 56, and the transistor 53. The light emitting element 51 still emits light.

### <No Light Emission>

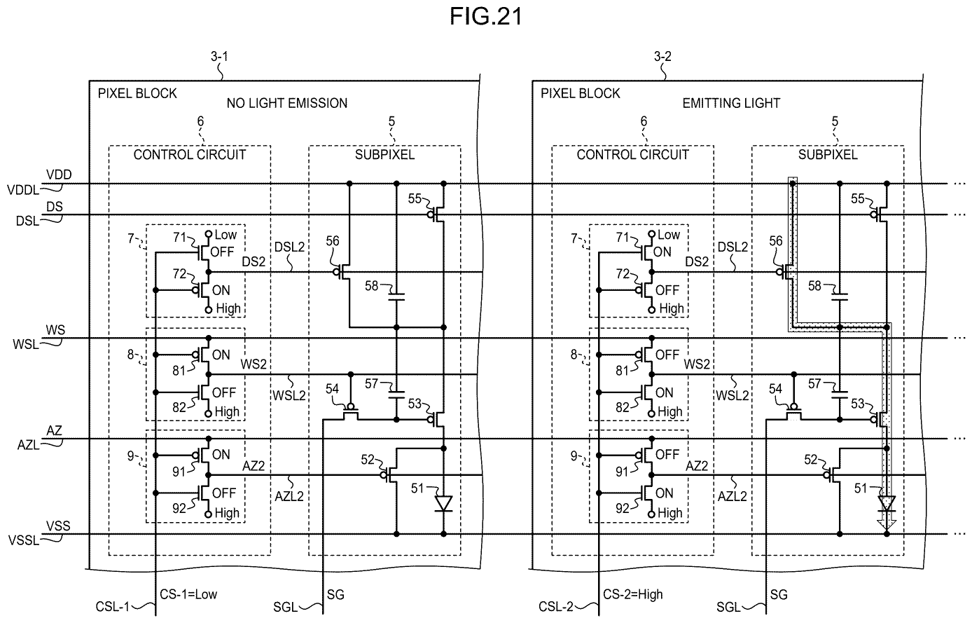

FIG. 21 illustrates an operation related to no light emission in the pixel block 3-1. The control signal DS and the control signal WS are high voltage signals, and the control signal AZ is a low voltage signal. In both the pixel block 3-1 and the pixel block 3-2, the transistor 55 is OFF.

In the pixel block 3-1, the control signal DS2 is a high voltage signal. The transistor 56 is OFF. The control signal WS2 is the control signal WS, namely, a high voltage signal. The transistor 54 is OFF. The control signal AZ2 is the control signal AZ, namely, a low voltage signal. The transistor 52 is ON. No current flows through the light emitting element 51, and the light emitting element 51 emits no light.

In the pixel block 3-2, the control signal DS2 is a low voltage signal. The transistor 56 is ON. The control signal WS2 is a high voltage signal. The transistor 54 is OFF. The control signal AZ2 is a high voltage signal. The transistor 52 is OFF. The current from the power supply line VDDL is supplied to the light emitting element 51 via the transistor 56 and the transistor 53. The light emitting element 51 still emits light.

For example, as described above, each of the pixel blocks 3 can be controlled such that the pixel blocks 3-2 continue to emit light without being refreshed while the pixel blocks 3-1 are refreshed. That is, each of the pixel blocks 3 included in the display panel 2 can be caused to operate as a pixel block 3-1 or a pixel block 3-2.

### 2. Application Examples

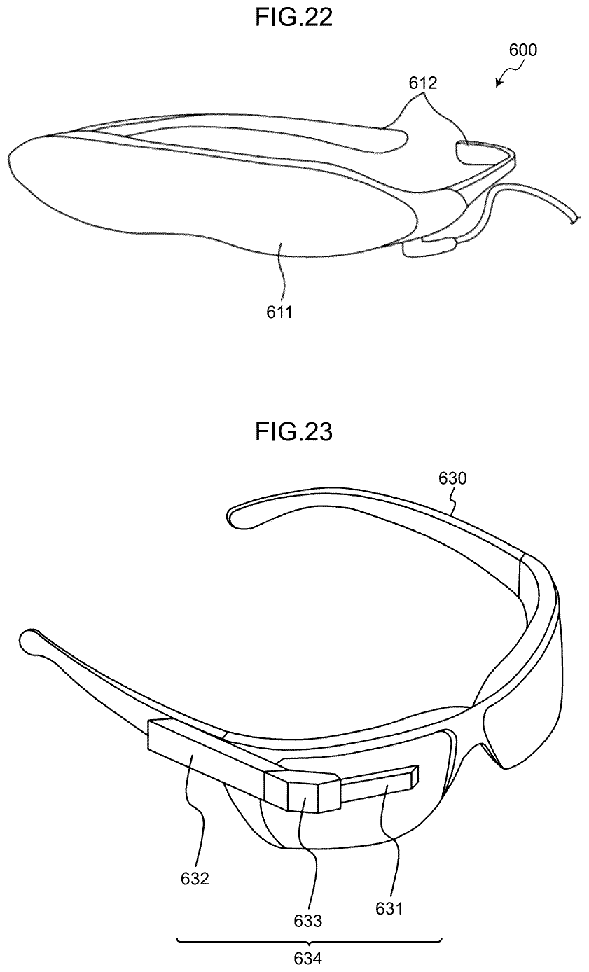

The display device 1 described above may be mounted on various electronic devices and used therein. An example of the electronic device is an HMD. This will be described with reference to FIGS. 22 and 23.

FIGS. 22 and 23 are diagrams illustrating examples of an electronic device. As the electronic device, an HMD is illustrated as an example. An HMD 600 illustrated in FIG. 22 includes a spectacle-shaped display unit 611 and ear hooking units 612 to be worn on the head of a user, the ear hooking units 612 located on both sides of the display unit 611. For example, the display device 1 described above can be used for the display unit 611 of the HMD600. An HMD 634 illustrated in FIG. 23 is a see-through type HMD and includes a main body 632, an arm 633, and a lens barrel 631. The main body 632 is connected with the arm 633 and spectacles 630. Specifically, the end of the main body 632 in the longitudinal direction is coupled to the arm 633, and one of side faces of the main body 632 is coupled to the spectacles 630 via a coupling member. Note that the main body 632 may be directly mounted on the head of the user. The main body 632 incorporates a control board for controlling the operation of the HMD 634 and a display unit. The arm 633 connects the main body 632 and the lens barrel 631 and supports the lens barrel 631. Specifically, the arm 633 is coupled to an end of the main body 632 and an end of the lens barrel 631 and fixes the lens barrel 631. Furthermore, the arm 633 incorporates a signal line for communicating data related to an image provided from the main body 632 to the lens barrel 631. The lens barrel 631 projects image light provided from the main body 632 via the arm 633 toward the eyes of the user wearing the HMD 634 through an eyepiece. The display device 1 described above can also be used for the display unit of the HMD 634, for example.

### 3. Exemplary Effects

The technology described above is specified as follows, for example. One aspect of the disclosed technology is the display device 1. As described with reference to FIGS. 1 to 7 and others, the display device 1 includes the display panel 2 including a plurality of pixels 4 and the control unit 10 that controls the display panel 2. The display panel 2 includes the plurality of pixel blocks 3 each including one or more pixels 4. The plurality of pixel blocks 3 include the pixel blocks 3-1 (first pixel blocks) and the pixel blocks 3-2 (second pixel blocks). The control unit 10 controls the display panel 32 such that the refresh rate of pixels 4 in the pixel blocks 3-2 (second pixel blocks) is lower than the refresh rate of pixels 4 in the pixel blocks 3-1 (first pixel blocks).

According to the above display device 1, power consumption and heat generation can be suppressed as the refresh rate of the pixel blocks 3-2 is decreased.

As described with reference to FIGS. 2 to 7 and others, the control unit 10 may control the display panel 2 such that the pixels 4 in the pixel blocks 3-2 continue to emit light without being refreshed while the pixels 4 in the pixel block 3-1 are refreshed repeatedly twice or more. For example, in this manner, the refresh rate of the pixels 4 in the pixel blocks 3-2 can be made lower than the refresh rate of the pixels 4 in the pixel block 3-1.

As described with reference to FIGS. 1 to 6 and others, the pixel blocks 3-1 may be located closer to the center of the display panel 2 than the pixel blocks 3-2 are. The display device 1 may include the detection unit 11 that detects the line of sight of the user, and the control unit 10 may select the pixel blocks 3-1 and the pixel blocks 3-2 from the plurality of pixel blocks 3 on the basis of the detection result of the detection unit 11. As a result, for example, the display can be performed at a high refresh rate in a region of the display panel 2 corresponding to the center of the field of view of the user (corresponding to the region R).

As described with reference to FIGS. 1 to 6, 15 to 21, and others, each of the plurality of pixel blocks 3 may include a control circuit 6 connected to the pixels 4 in the pixel block 3, and the control circuit 6 may cause the pixel block 3 including the control circuit 6 to operate as a pixel block 3-1 or a pixel block 3-2 on the basis of the control signal CS from the control unit 10. For example, by including such a control circuit 6, each of the pixel blocks 3 can be caused to operate as a pixel block 3-1 or a pixel block 3-2.

As described with reference to FIGS. 15 to 21 and others, a pixel 4 may include a light emitting element 51 and a transistor included in a drive circuit of the light emitting element 51, and the control circuit 6 may control the transistor. The transistor may include a transistor 52 (initialization transistor) connected in parallel to the light emitting element 51, a transistor 54 for sampling a pixel signal (an example of the control signal SG) (sampling transistor), and a transistor 56 (second light emission controlling transistor) connected in parallel to a transistor 55 (light emission controlling transistor) connected between a transistor 53 (drive transistor) for supplying a current corresponding to a pixel signal to the light emitting element 51 and the power supply line VDDL, and the control circuit 6 may cause the pixel block 3 including the control circuit 6 to operate as a pixel block 3-2 by turning on the transistor 56 and turning off the transistor 54 and the transistor 52. The control circuit 6 may include a switch circuit 7 (first switch circuit) connected to the transistor 56, a switch circuit 8 (second switch circuit) connected between the control line WSL for supplying the control signal WS from the control unit 10 to the control terminal of the transistor 54 and the control terminal of the transistor 54, and a switch circuit 9 (third switch circuit) connected between the control line AZL for supplying the control signal AZ from the control unit 10 to the control terminal of the transistor 52 and the control terminal of the transistor 52. In a case where the control circuit 6 causes the pixel block 3 including the control circuit 6 to operate as a pixel block 3-1, the switch circuit 7 may turn off the transistor 56, the switch circuit 8 may supply the control signal WS from the control unit 10 to the control terminal of the transistor 54, and the switch circuit 9 may supply the control signal AZ from the control unit 10 to the control terminal of the transistor 52. In a case where the control circuit 6 causes the pixel block 3 including the control circuit 6 to operate as a pixel block 3-2, the switch circuit 7 may turn on the transistor 56, the switch circuit 8 may turn off the transistor 54, and the switch circuit 9 may turn off the transistor 52. For example, in such a circuit configuration, each of the pixel blocks 3 can be caused to operate as a pixel block 3-1 or a pixel block 3-2.

As described with reference to FIG. 7 and others, the control unit 10 may control the display panel 2 such that the light emission luminance B1 of the pixels 4 in the pixel blocks 3-1 is larger than the light emission luminance B2 of the pixels 4 in the pixel blocks 3-2. The control unit 10 may control the light emission luminance B1 of the pixels 4 in the pixel blocks 3-1 and the light emission luminance B2 of the pixels 4 in the pixel block 3-2 on the basis of the ratio between the light emission period T1 of the pixels 4 in the pixel blocks 3-1 and the light emission period T2 of the pixels 4 in the pixel blocks 3-2. As a result, it is possible to balance (for example, match) the luminance of the pixel blocks 3-1 and that of the pixel blocks 3-2 over the plurality of frames as a whole.

The control method for the display panel 2 described with reference to FIG. 8 and others is also one aspect of the disclosed technology. The control method is a control method for the display panel 2 including the plurality of pixels 4 and may include controlling the display panel 2 such that the refresh rate of the pixels 4 in the pixel blocks 3-2 (second pixel blocks) is lower than the refresh rate of the pixels 4 in the pixel blocks 3-1 (first pixel blocks) (step S3). Also by such a control method, as described above, power consumption and heat generation can be suppressed.

An electronic device including the display device 1 such as the HMD 600 or the HMD 634 as described with reference to FIGS. 22 and 23 and others is also one aspect of the disclosed technology. As described above, power consumption and heat generation can be suppressed.

Note that the effects described herein are merely examples, and it is not limited to the disclosed content. There may be other effects.

Although the embodiments of the disclosure have been described above, the technical scope of the disclosure is not limited to the above embodiments as they are, and various modifications can be made without departing from the gist of the disclosure. In addition, components of different embodiments and modifications may be combined as appropriate.

Note that the present technology can also have the following configurations.
(1) A display device comprising:
   a display panel including a plurality of pixels; and
   a control unit that controls the display panel, wherein
   the display panel includes a plurality of pixel blocks each including one or more of the pixels,
   the plurality of pixel blocks includes a first pixel block and a second pixel block, and
   the control unit controls the display panel such that a refresh rate of a pixel in the second pixel block is lower than a refresh rate of a pixel in the first pixel block.
(2) The display device according to (1), wherein
   the control unit controls the display panel such that the pixel in the second pixel block continues to emit light without being refreshed while the pixel in the first pixel block is repeatedly refreshed twice or more.
(3) The display device according to (1) or (2), wherein
   the first pixel block is located closer to a center of the display panel than the second pixel block is.
(4) The display device according to any one of (1) to (3), comprising:
   a detection unit that detects a line of sight of a user, wherein
   the control unit selects the first pixel block and the second pixel block from the plurality of pixel blocks on a basis of a detection result of the detection unit.
(5) The display device according to any one of (1) to (4), wherein
   each of the plurality of pixel blocks includes a control circuit connected to a pixel in the pixel block, and
   the control circuit causes a pixel block including the control circuit to operate as the first pixel block or the second pixel block on a basis of a control signal from the control unit.
(6) The display device according to (5), wherein
   the pixel includes a light emitting element and a transistor included in a drive circuit of the light emitting element, and
   the control circuit controls the transistor.
(7) The display device according to (6), wherein
   the transistor includes:
   an initialization transistor connected in parallel to the light emitting element;
   a sampling transistor for sampling a pixel signal; and
   a second light emission controlling transistor connected in parallel to a light emission controlling transistor connected between a drive transistor and a power supply line, the drive transistor for supplying a current corresponding to the pixel signal to the light emitting element, and
   the control circuit causes a pixel block including the control circuit to operate as the second pixel block by turning on the second light emission controlling transistor and turning off the sampling transistor and the initialization transistor.
(8) The display device according to (7), wherein
   the control circuit includes:
   a first switch circuit connected to the second light emission controlling transistor;
   a second switch circuit connected between a control line for supplying a control signal from the control unit to a control terminal of the sampling transistor and the control terminal of the sampling transistor; and
   a third switch circuit connected between a control line for supplying a control signal from the control unit to a control terminal of the initialization transistor and the control terminal of the initialization transistor,
   in a case where the control circuit causes a pixel block including the control circuit to operate as the first pixel block, the first switch circuit turns off the second light emission controlling transistor, the second switch circuit supplies a control signal from the control unit to the control terminal of the sampling transistor, and the third switch circuit supplies a control signal from the control unit to the control terminal of the initialization transistor, and
   in a case where the control circuit causes the pixel block including the control circuit to operate as the second pixel block, the first switch circuit turns on the second light emission controlling transistor, the second switch circuit turns off the sampling transistor, and the third switch circuit turns off the initialization transistor.
(9) The display device according to any one of (1) to (8), wherein
   the control unit controls the display panel such that light emission luminance of a pixel in the first pixel block is larger than light emission luminance of a pixel in the second pixel block.
(10) The display device according to (9), wherein
   the control unit controls the light emission luminance of the pixel in the first pixel block and the light emission luminance of the pixel in the second pixel block on a basis of a ratio between a light emission period of the pixel in the first pixel block and a light emission period of the pixel in the second pixel block.
(11) A control method for a display panel including a plurality of pixels, wherein
   the display panel includes a plurality of pixel blocks each including one or more of the pixels, and
   the plurality of pixel blocks includes a first pixel block and a second pixel block,
   the control method comprising:
   controlling the display panel such that a refresh rate of a pixel in the second pixel block is lower than a refresh rate of a pixel in the first pixel block.
(12) An electronic device comprising:
   a display device, wherein
   the display device includes:
   a display panel including a plurality of pixels; and
   a control unit that controls the display panel,
   the display panel includes a plurality of pixel blocks each including one or more of the pixels,
   the plurality of pixel blocks includes a first pixel block and a second pixel block, and
   the control unit controls the display panel such that a refresh rate of a pixel in the second pixel block is lower than a refresh rate of a pixel in the first pixel block.

### REFERENCE SIGNS LIST

1 DISPLAY DEVICE
2 DISPLAY PANEL
3 PIXEL BLOCK
3-1 PIXEL BLOCK (FIRST PIXEL BLOCK)
3-2 PIXEL BLOCK (SECOND PIXEL BLOCK)
4 PIXEL
5 SUBPIXEL
51 LIGHT EMITTING ELEMENT
52 TRANSISTOR (INITIALIZATION TRANSISTOR)
53 TRANSISTOR (DRIVE TRANSISTOR)
54 TRANSISTOR (SAMPLING TRANSISTOR)
55 TRANSISTOR (LIGHT EMISSION CONTROLLING TRANSISTOR)
56 TRANSISTOR (SECOND LIGHT EMISSION CONTROLLING TRANSISTOR)
57 CAPACITOR
58 CAPACITOR
6 CONTROL CIRCUIT
7 SWITCH CIRCUIT (FIRST SWITCH CIRCUIT)
71 TRANSISTOR
72 TRANSISTOR
8 SWITCH CIRCUIT (SECOND SWITCH CIRCUIT)
81 TRANSISTOR
82 TRANSISTOR
9 SWITCH CIRCUIT (THIRD SWITCH CIRCUIT)
91 TRANSISTOR
92 TRANSISTOR
10 CONTROL UNIT
101 CONTROL UNIT
102 CONTROL UNIT
11 DETECTION UNIT
AZ CONTROL SIGNAL
AZL CONTROL LINE
AZ2 CONTROL SIGNAL
AZL2 CONTROL LINE
DS CONTROL SIGNAL
DSL CONTROL LINE
DS2 CONTROL SIGNAL
DSL2 CONTROL LINE
WS CONTROL SIGNAL
WSL CONTROL LINE
WS2 CONTROL SIGNAL
WSL2 CONTROL LINE
VDD POWER SUPPLY VOLTAGE
VDDL POWER SUPPLY LINE
VSS REFERENCE VOLTAGE
VSSL POWER SUPPLY LINE
B1 LIGHT EMISSION LUMINANCE
T1 LIGHT EMISSION PERIOD
B2 LIGHT EMISSION LUMINANCE
T2 LIGHT EMISSION PERIOD
R REGION

1. A display device comprising:
a display panel including a plurality of pixels; and
a control unit that controls the display panel, wherein
the display panel includes a plurality of pixel blocks each including one or more of the pixels,
the plurality of pixel blocks includes a first pixel block and a second pixel block, and
the control unit controls the display panel such that a refresh rate of a pixel in the second pixel block is lower than a refresh rate of a pixel in the first pixel block.

2. The display device according to claim 1, wherein
the control unit controls the display panel such that the pixel in the second pixel block continues to emit light without being refreshed while the pixel in the first pixel block is repeatedly refreshed twice or more.

3. The display device according to claim 1, wherein
the first pixel block is located closer to a center of the display panel than the second pixel block is.

4. The display device according to claim 1, comprising:
a detection unit that detects a line of sight of a user, wherein
the control unit selects the first pixel block and the second pixel block from the plurality of pixel blocks on a basis of a detection result of the detection unit.

5. The display device according to claim 1, wherein
each of the plurality of pixel blocks includes a control circuit connected to a pixel in the pixel block, and
the control circuit causes a pixel block including the control circuit to operate as the first pixel block or the second pixel block on a basis of a control signal from the control unit.

6. The display device according to claim 5, wherein
the pixel includes a light emitting element and a transistor included in a drive circuit of the light emitting element, and
the control circuit controls the transistor.

7. The display device according to claim 6, wherein
the transistor includes:
an initialization transistor connected in parallel to the light emitting element;
a sampling transistor for sampling a pixel signal; and
a second light emission controlling transistor connected in parallel to a light emission controlling transistor connected between a drive transistor and a power supply line, the drive transistor for supplying a current corresponding to the pixel signal to the light emitting element, and
the control circuit causes a pixel block including the control circuit to operate as the second pixel block by turning on the second light emission controlling transistor and turning off the sampling transistor and the initialization transistor.

8. The display device according to claim 7, wherein
the control circuit includes:
a first switch circuit connected to the second light emission controlling transistor;
a second switch circuit connected between a control line for supplying a control signal from the control unit to a control terminal of the sampling transistor and the control terminal of the sampling transistor; and
a third switch circuit connected between a control line for supplying a control signal from the control unit to a control terminal of the initialization transistor and the control terminal of the initialization transistor,
in a case where the control circuit causes a pixel block including the control circuit to operate as the first pixel block, the first switch circuit turns off the second light emission controlling transistor, the second switch circuit supplies a control signal from the control unit to the control terminal of the sampling transistor, and the third switch circuit supplies a control signal from the control unit to the control terminal of the initialization transistor, and
in a case where the control circuit causes the pixel block including the control circuit to operate as the second pixel block, the first switch circuit turns on the second light emission controlling transistor, the second switch circuit turns off the sampling transistor, and the third switch circuit turns off the initialization transistor.

9. The display device according to claim 1, wherein
the control unit controls the display panel such that light emission luminance of a pixel in the first pixel block is larger than light emission luminance of a pixel in the second pixel block.

10. The display device according to claim 9, wherein
the control unit controls the light emission luminance of the pixel in the first pixel block and the light emission luminance of the pixel in the second pixel block on a basis of a ratio between a light emission period of the pixel in the first pixel block and a light emission period of the pixel in the second pixel block.

11. A control method for a display panel including a plurality of pixels, wherein
the display panel includes a plurality of pixel blocks each including one or more of the pixels, and
the plurality of pixel blocks includes a first pixel block and a second pixel block,
the control method comprising:
controlling the display panel such that a refresh rate of a pixel in the second pixel block is lower than a refresh rate of a pixel in the first pixel block.

12. An electronic device comprising:
a display device, wherein
the display device includes:
a display panel including a plurality of pixels; and
a control unit that controls the display panel,
the display panel includes a plurality of pixel blocks each including one or more of the pixels,
the plurality of pixel blocks includes a first pixel block and a second pixel block, and
the control unit controls the display panel such that a refresh rate of a pixel in the second pixel block is lower than a refresh rate of a pixel in the first pixel block.
